(19) United States
(12) Patent Application Publication
(10) Pub. No.: US 2026/0020161 A1
(43) Pub. Date: Jan. 15, 2026

(54) WIRE HARNESS

(71) Applicant: YAZAKI CORPORATION, Tokyo (JP)

(72) Inventors: Tatsuya Oga, Makinohara-shi (JP); Katsunori Sato, Makinohara-shi (JP); Mariko Nakagawa, Makinohara-shi (JP); Seigo Mochizuki, Fujieda-shi (JP)

(21) Appl. No.: 19/234,213

(22) Filed: Jun. 10, 2025

(30) Foreign Application Priority Data
Jul. 11, 2024 (JP) 2024-111500

(51) Int. Cl. H05K 1/18; H01H 85/02; H01M 50/519; H01M 50/583; H01M 50/588

(52) U.S. Cl. CPC H05K 1/189; H01H 85/0241; H01M 50/519; H01M 50/583; H01M 50/588; H01H 2085/0275; H01M 2200/103; H05K 2201/10181

(57) ABSTRACT

A wire harness includes: a flexible printed circuit board; a chip fuse mounted on the flexible printed circuit board; a plate member having a flat plate-shaped plate body having a frame shape, and a cylindrical peripheral wall protruding from the plate body in a thickness direction of the plate body; and a potting agent, in which the plate body is fixed to the flexible printed circuit board so as to surround the chip fuse by the peripheral wall, and the potting agent is charged in a space portion surrounded by the peripheral wall and covers the chip fuse.

### CROSS-REFERENCE TO RELATED APPLICATION(S)

The present application claims priority to and incorporates by reference the entire contents of Japanese Patent Application No. 2024-111500 filed in Japan on Jul. 11, 2024.

### BACKGROUND OF THE INVENTION

### 1. Field of the Invention

The present invention relates to a wire harness.

### 2. Description of the Related Art

Conventionally, there is a technique of covering an electronic component with a potting agent. JP 2023-173 467 A discloses a conductive module including a flexible printed wiring board, an electronic component mounted on the flexible printed wiring board, a metal plate having a frame portion surrounding the electronic component, and a potting agent that is charged in a region surrounded by the frame portion and covers the electronic component.

In JP 2023-173 467 A, when a metal plate having a thickness corresponding to the required depth of a potting layer is used, the weight of the metal plate tends to increase. It is desirable to be able to reduce the weight of the plate member while realizing the required depth of the potting layer.

### SUMMARY OF THE INVENTION

An object of the present invention is to provide a wire harness capable of reducing the weight of the plate member while realizing the required depth of the potting layer.

In order to achieve the above mentioned object, a wire harness according to one aspect of the present invention includes a flexible printed circuit board; a chip fuse mounted on the flexible printed circuit board; a plate member having a flat plate-shaped plate body having a frame shape, and a cylindrical peripheral wall protruding from the plate body in a thickness direction of the plate body; and a potting agent, wherein the plate body is fixed to the flexible printed circuit board so as to surround the chip fuse by the peripheral wall, and the potting agent is charged in a space portion surrounded by the peripheral wall and covers the chip fuse.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a diagram illustrating a wire harness according to an embodiment;

FIG. 2 is an exploded perspective view of the wire harness according to the embodiment;

FIG. 3 is a plan view of a flexible printed circuit board according to the embodiment;

FIG. 4 is a plan view of a plate member according to the embodiment;

FIG. 5 is a cross-sectional view of the plate member according to the embodiment;

FIG. 6 is a plan view of the wire harness according to the embodiment;

FIG. 7 is a cross-sectional view of the wire harness according to the embodiment;

FIG. 8 is a plan view of another wire harness according to the embodiment; and

FIG. 9 is a cross-sectional view of another wire harness according to the embodiment.

### DETAILED DESCRIPTION OF THE PREFERRED EMBODIMENTS

A wire harness according to embodiments of the present invention will be described in detail below with reference to the drawings. Note that the present invention is not limited by the embodiments. Further, the components in the following embodiments include those which can be easily assumed by those skilled in the art or those which are substantially the same.

### EMBODIMENT

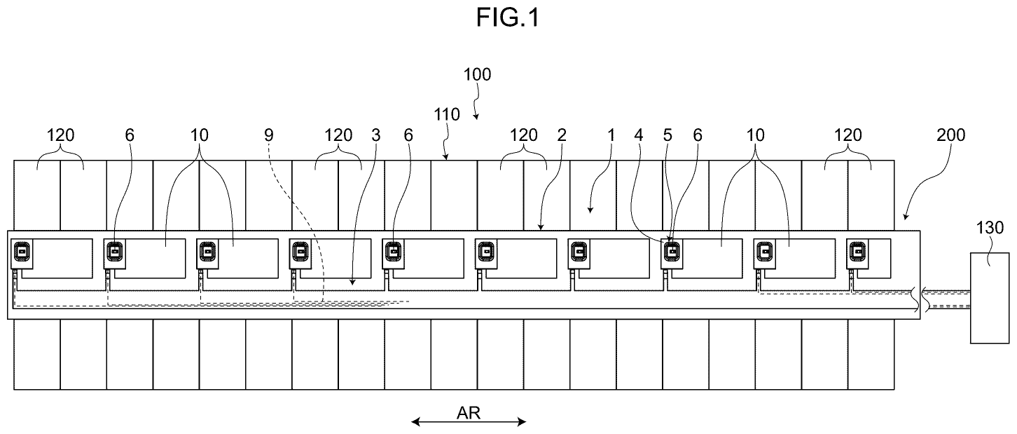

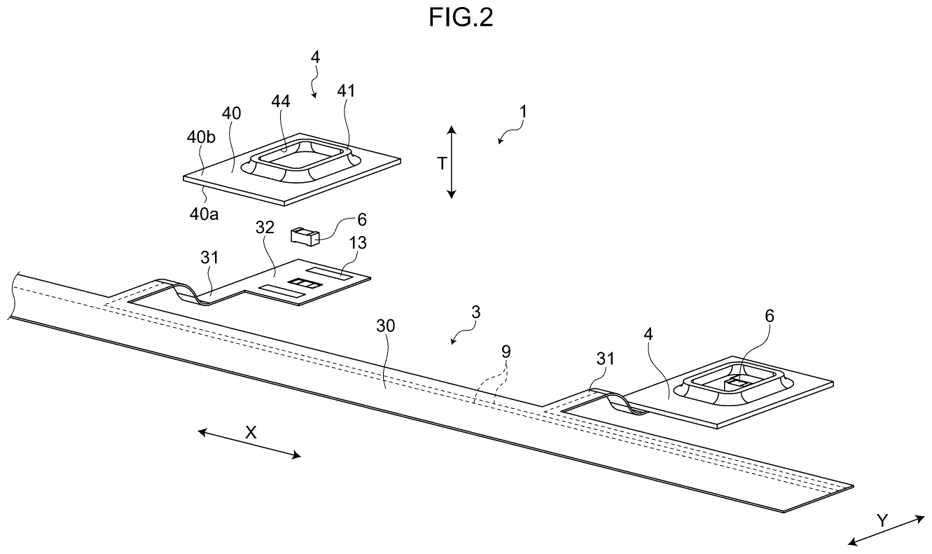

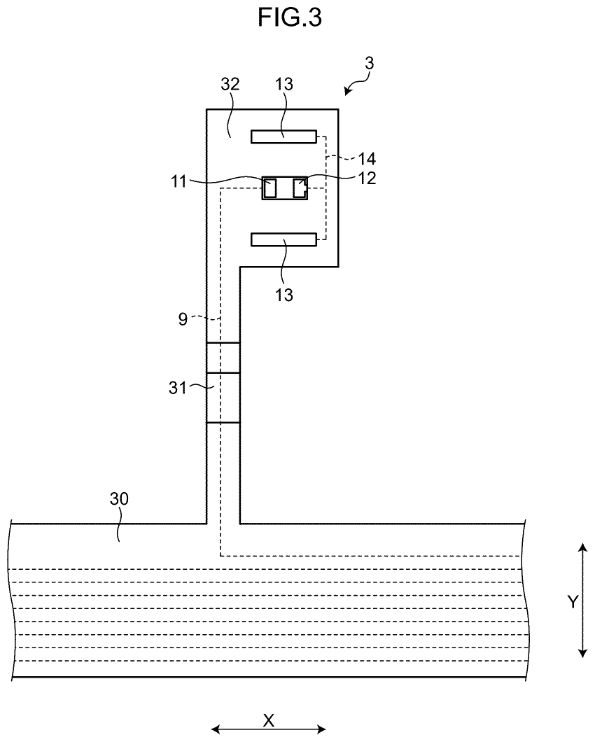

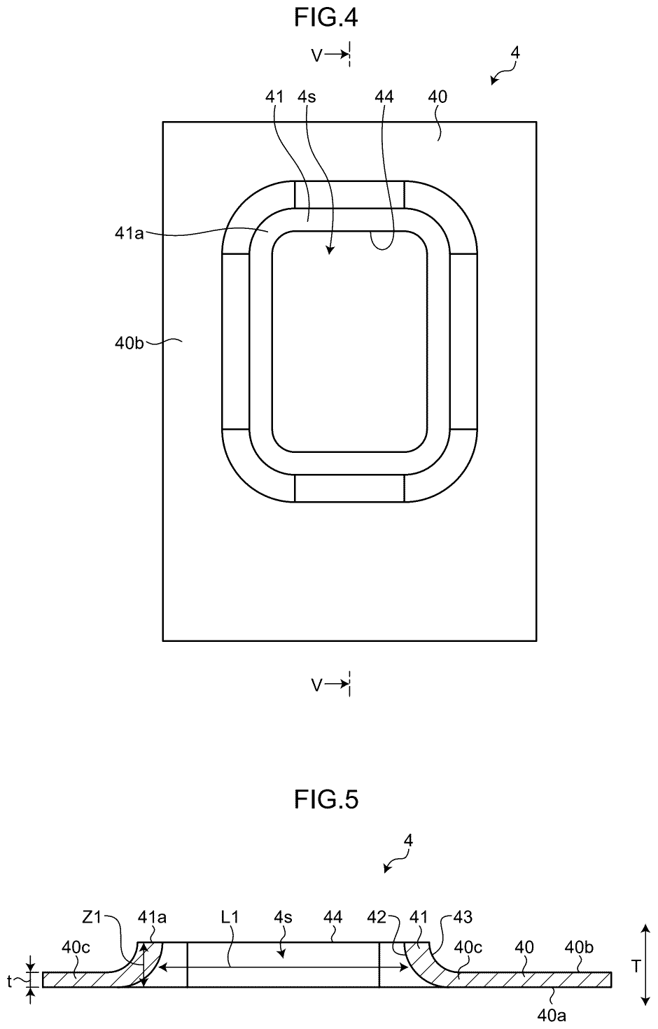

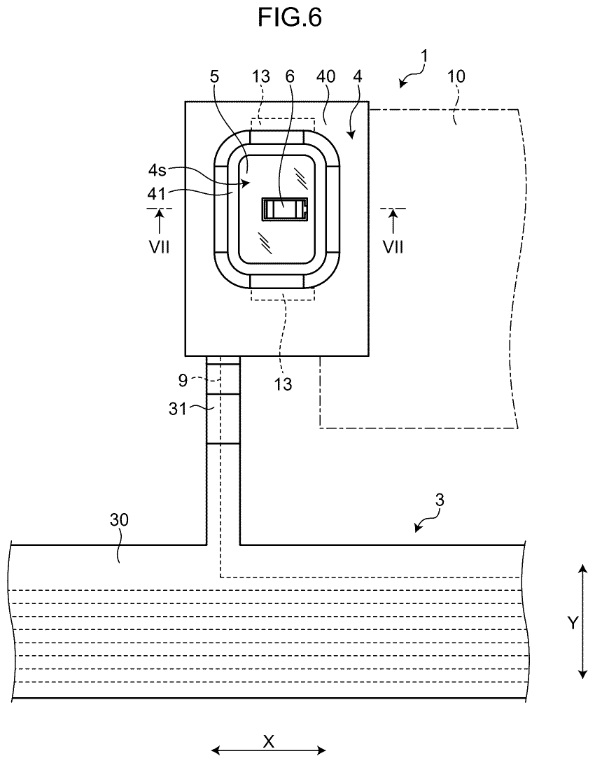

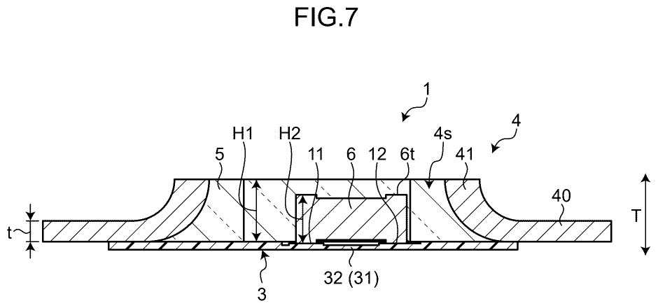

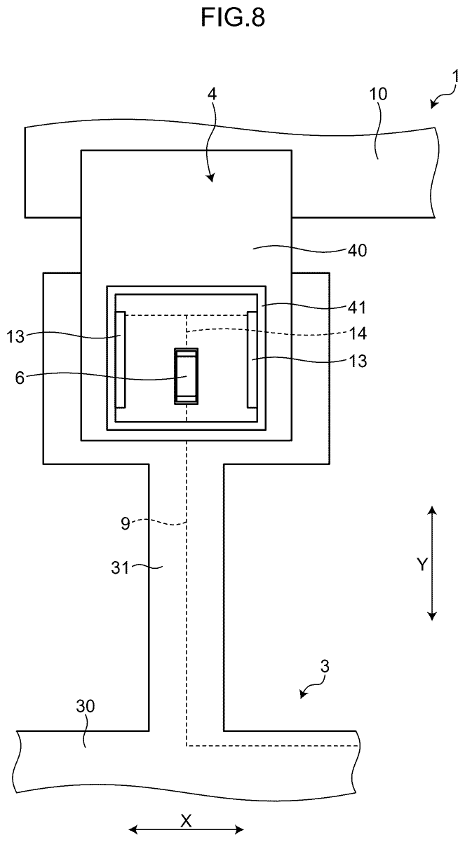

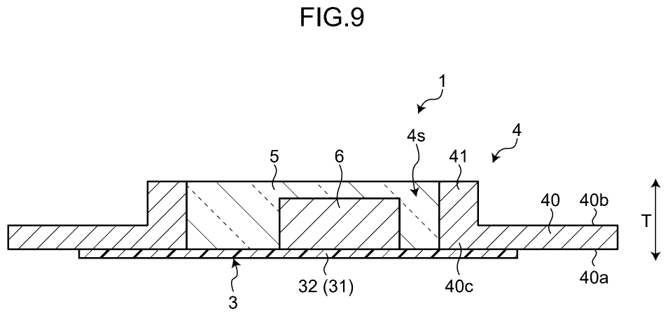

An embodiment will be described with reference to FIGS. 1 to 9. The present embodiment relates to a wire harness. FIG. 1 is a diagram illustrating a wire harness according to the embodiment, FIG. 2 is an exploded perspective view of the wire harness according to the embodiment, FIG. 3 is a plan view of a flexible printed circuit board according to the embodiment, FIG. 4 is a plan view of a plate member according to the embodiment, FIG. 5 is a cross-sectional view of the plate member according to the embodiment, FIG. 6 is a plan view of the wire harness according to the embodiment, FIG. 7 is a cross-sectional view of the wire harness according to the embodiment, FIG. 8 is a plan view of another wire harness according to the embodiment, and FIG. 9 is a cross-sectional view of another wire harness according to the embodiment. FIG. 5 illustrates a cross section taken along line V-V of FIG. 4. FIG. 7 illustrates a cross section taken along line VII-VII of FIG. 6.

As illustrated in FIG. 1, a wire harness 1 of the present embodiment has a flexible printed circuit board 3, a chip fuse 6, a plate member 4, and a potting agent 5. In the illustrated wire harness 1, a plurality of chip fuses 6 is mounted on the flexible printed circuit board 3. In addition, a plurality of plate members 4 is disposed on the flexible printed circuit board 3 in accordance with the plurality of chip fuses 6. The wire harness 1 can be combined with a case 2 and a plurality of bus bars 10 to constitute a bus bar module 200.

The wire harness 1 and the bus bar module 200 are applied to, for example, a battery module 110 of a battery pack 100. The battery module 110 has a plurality of battery cells 120 arranged in an arrangement direction AR. The battery pack 100 is mounted, for example, as a power source in a vehicle such as an electric vehicle or a hybrid electric vehicle.

The bus bar 10 is a conductor formed of a conductive metal plate, and is fixed to an electrode of the battery cell 120. The bus bar 10 connects, for example, two adjacent battery cells 120 in series. The flexible printed circuit board 3 connects the plurality of bus bars 10 to a monitoring device 130 of the battery pack 100. The flexible printed circuit board 3 may connect a thermistor disposed in the battery cell 120 to the monitoring device 130. The monitoring device 130 is a device that monitors a state such as a voltage or a temperature of the battery cell 120.

The flexible printed circuit board 3 is connected to the monitoring device 130 via a connector, for example. The flexible printed circuit board 3 has a plurality of detection lines 9. Each detection line 9 is a circuit pattern formed of a conductive metal. The detection line 9 is connected to a circuit of the monitoring device 130.

The detection line 9 is connected to the bus bar 10 via the chip fuse 6 mounted on the flexible printed circuit board 3. The chip fuse 6 is a protective component that protects the circuit. The chip fuse 6 has two electrodes and a fusible portion. The fusible portion melts when an overcurrent flows between the two electrodes.

In the wire harness 1 of the present embodiment, the plate member 4 is interposed between the chip fuse 6 and the bus bar 10. The plate member 4 is connected to the bus bar 10 by welding or the like, and electrically connects the chip fuse 6 and the bus bar 10. The plate member 4 of the present embodiment is disposed on the flexible printed circuit board 3 as a voltage detection terminal for detecting the voltage of the battery cell 120. The plate member 4 has a function as a reinforcing plate for reinforcing the flexible printed circuit board 3. In addition, the plate member 4 has a space portion 4s that accommodates the chip fuse 6. As will be described below, the potting agent 5 is charged in the space portion 4s formed by the plate member 4 and covers the chip fuse 6.

The case 2 accommodates and holds the flexible printed circuit board 3 and the bus bar 10. The case 2 is molded of, for example, an insulating synthetic resin. The case 2 has a routing path in which the flexible printed circuit board 3 is routed, and a plurality of holding portions arranged along the routing path. Each bus bar 10 is held by a corresponding holding portion. The wire harness 1 may have a cover that covers the flexible printed circuit board 3 and the bus bar 10. In this case, the cover may be integrated with the case 2.

As illustrated in FIG. 2, the flexible printed circuit board 3 has one trunk line 30 and a plurality of branch portions 31. The flexible printed circuit board 3 has a base film, a cover lay, and a conductive layer. The base film and the cover lay are flexible insulating resin layers. The conductive layer is protected by being sandwiched between the base film and the cover lay. The conductive layer is, for example, a conductive metal foil, and has a plurality of circuit patterns including the detection line 9.

The trunk line 30 has a longitudinal direction X and a width direction Y. The width direction Y is orthogonal to the longitudinal direction X. The plurality of detection lines 9 extends in the trunk line 30. The branch portion 31 is branched from an edge of the trunk line 30 in the width direction Y. The branch portion 31 of the present embodiment extends from the trunk line 30 in the width direction Y.

The chip fuse 6 is mounted on a mounting region 32 provided at the tip of the branch portion 31. The mounting region 32 is a region widened in the longitudinal direction X, and has a substantially rectangular shape. The plate member 4 is fixed to the flexible printed circuit board 3 so as to surround the chip fuse 6 by a peripheral wall 41.

As illustrated in FIG. 3, the conductive layer of the flexible printed circuit board 3 has the detection line 9, a first pad 11, a second pad 12, a third pad 13, and a connection line 14. The first pad 11, the second pad 12, the third pad 13, and the connection line 14 are disposed in the mounting region 32 of the branch portion 31. The pads 11, 12, and 13 are exposed to the external space. In other words, the cover lay is provided with an opening that exposes the pads 11, 12, and 13.

The illustrated first pad 11 and second pad 12 are arranged along the longitudinal direction X. The first pad 11 and the second pad 12 are joint portions to which electrodes of the chip fuse 6 are connected. The electrodes of the chip fuse 6 are joined to the pads 11 and 12 by solder, for example. The two electrodes are joined to the pads 11 and 12, so that the chip fuse 6 is mounted on the flexible printed circuit board 3. One of the two electrodes of the chip fuse 6 is connected to the first pad 11, and the other electrode is connected to the second pad 12. That is, the chip fuse 6 is mounted on the branch portion 31 so as to extend in the longitudinal direction X. The detection line 9 is connected to the first pad 11 from the trunk line 30 via the branch portion 31.

The third pad 13 is a joint portion to which the plate member 4 is connected. The plate member 4 is joined to the third pad 13 by solder, for example, and is mounted on the flexible printed circuit board 3. Two third pads 13 are provided in the mounting region 32 of the present embodiment. The two third pads 13 are disposed on both sides of the pads 11 and 12 in the width direction Y. The connection line 14 connects the second pad 12 and the two third pads 13. Therefore, the third pad 13 is connected to the detection line 9 via the connection line 14 and the chip fuse 6.

As illustrated in FIGS. 2, 4, and 5, the plate member 4 has a plate body 40 and a cylindrical peripheral wall 41. The plate member 4 is a member that forms the space portion 4s to be filled with the potting agent 5, and has rigidity. The plate member 4 is formed of, for example, a conductive metal. The plate member 4 has an opening 44 and is fixed to the flexible printed circuit board 3 so that the opening 44 faces the chip fuse 6. The shape of the illustrated opening 44 is rectangular.

The plate body 40 is formed in a flat plate shape and has a frame shape. The shape of the illustrated plate body 40 is a rectangular frame shape. The plate body 40 has a first surface 40a and a second surface 40b. The first surface 40a and the second surface 40b are two main surfaces of the plate body 40. The first surface 40a is a flat surface and is connected to the third pad 13 of the flexible printed circuit board 3. That is, the first surface 40a is a surface facing the flexible printed circuit board 3 among the two main surfaces of the plate body 40. The second surface 40b is a flat surface and is a surface opposite to the first surface 40a.

The peripheral wall 41 protrudes from the plate body 40 in a thickness direction T of the plate body 40. The illustrated peripheral wall 41 protrudes from the second surface 40b in a direction orthogonal to the second surface 40b. A cross-sectional shape of the peripheral wall 41 in a cross section orthogonal to the thickness direction T is rectangular. That is, the illustrated peripheral wall 41 has a rectangular tubular shape. The peripheral wall 41 is formed by, for example, a burring process to a metal plate. In this case, the peripheral wall 41 is formed by a burring process to a flat plate-shaped metal plate, which is a base material of the plate member 4. The peripheral wall 41 is formed by deforming an edge portion surrounding the opening 44.

As illustrated in FIG. 5, the peripheral wall 41 communicates with an inner edge 40c of the plate body 40. In a cross section along the thickness direction T, the peripheral wall 41 is curved in a substantially arc shape. The peripheral wall 41 has an inner wall surface 42 and an outer wall surface 43. The inner wall surface 42 is a surface that faces the space portion 4s surrounded by the peripheral wall 41. The inner wall surface 42 is continuous with the first surface 40a of the plate body 40. The outer wall surface 43 is a surface of the peripheral wall 41 opposite to the inner wall surface 42. The outer wall surface 43 is continuous with the second surface 40b of the plate body 40.

The peripheral wall 41 has a tapered shape in which a distance L1 decreases with increasing distance from the plate body 40 along the thickness direction T. The distance L1 is a distance between the inner wall surfaces 42 facing each other. In the cross section of FIG. 5, the inner wall surface 42 and the outer wall surface 43 have a curved shape that is curved toward the space portion 4s.

The peripheral wall 41 has a tip surface 41a. A distance Z1 in the thickness direction T from the first surface 40a to the tip surface 41a is larger than the height of the chip fuse 6. That is, the peripheral wall 41 can form the space portion 4s having a depth capable of accommodating the entire chip fuse 6.

The metal plate constituting the plate member 4 has a thickness t. The thickness t of the plate body 40 is smaller than the distance Z1 from the first surface 40a to the tip surface 41a. That is, the depth (distance Z1) of the space portion 4s formed by the plate member 4 of the present embodiment is larger than the thickness t of the plate body 40.

FIG. 6 illustrates the chip fuse 6 and the plate member 4 mounted on the flexible printed circuit board 3. The plate body 40 of the plate member 4 is fixed to the flexible printed circuit board 3 so as to surround the chip fuse 6 by the peripheral wall 41. In other words, the plate body 40 is fixed to the flexible printed circuit board 3 so as to accommodate the chip fuse 6 in the space portion 4s surrounded by the peripheral wall 41. A gap for charging the potting agent 5 is provided between the peripheral wall 41 and the chip fuse 6.

In the wire harness 1 of the present embodiment, the plate body 40 is joined to the third pad 13 of the flexible printed circuit board 3 and is fixed to the flexible printed circuit board 3. The plate member 4 is connected to the detection line 9 via the chip fuse 6. The space portion 4s surrounded by the peripheral wall 41 is filled with the potting agent 5.

The bus bar 10 is disposed side by side with the branch portion 31 in the longitudinal direction X, for example. The plate body 40 of the plate member 4 is connected to the bus bar 10 by welding or the like. The plate body 40 is joined to the bus bar 10 such that, for example, an end portion of the plate body 40 overlaps the bus bar 10.

As illustrated in FIG. 7, the potting agent 5 is charged in the space portion 4s surrounded by the peripheral wall 41 and covers the chip fuse 6. A depth H1 of a potting layer is larger than a height H2 of the chip fuse 6. The potting agent 5 covers a top surface 6t of the chip fuse 6 and seals the chip fuse 6.

The thickness t of the plate body 40 of the present embodiment is smaller than the height H2 of the chip fuse 6. That is, in the wire harness 1 of the present embodiment, it is possible to realize the weight reduction by reducing the thickness t while forming the potting layer having the depth H1 capable of accommodating the entire chip fuse 6. For example, the weight of the plate member 4 can be reduced as compared with a case where the plate member is formed of a metal plate having the same thickness as the depth H1.

Note that the direction in which the plate member 4 extends and the relative position of the bus bar 10 with respect to the branch portion 31 can be set as appropriate. The direction in which the plate member 4 extends and the relative position of the bus bar 10 with respect to the branch portion 31 are determined corresponding to the battery module 110, for example. FIG. 8 illustrates the plate member 4 extending from the branch portion 31 in the width direction Y. The bus bar 10 of FIG. 8 is disposed side by side with the branch portion 31 in the width direction Y. The plate body 40 of the plate member 4 extends from the branch portion 31 in the width direction Y and is connected to the bus bar 10. The plate body 40 is fixed to the branch portion 31 of the flexible printed circuit board 3 so as to surround the chip fuse 6 by the peripheral wall 41. In the flexible printed circuit board 3 of FIG. 8, two third pads 13 are disposed on both sides of the chip fuse 6 in the longitudinal direction X. The plate body 40 is connected to the third pad 13 by solder or the like.

Note that the method of forming the peripheral wall 41 on the plate member 4 is not limited to the burring process. For example, the plate body 40 and the peripheral wall 41 may be formed by a process such as cutting process to a metal plate. For example, the plate body 40 and the peripheral wall 41 may be formed by cutting an outer edge portion of a metal plate to reduce the thickness. FIG. 9 illustrates an example of the plate member 4 formed of a single metal plate. In the plate member 4 of FIG. 9, the peripheral wall 41 is orthogonal to the plate body 40. The plate member 4 having the plate body 40 and the peripheral wall 41 may be formed by casting or forging.

The plate member 4 may be constituted by joining a plurality of members. For example, the plate member 4 may be constituted by joining a flat plate-shaped first member having a frame shape and a cylindrical second member. In this case, the flat plate-shaped first member constitutes the plate body 40, and the cylindrical second member constitutes the peripheral wall 41. The plurality of members constituting the plate member 4 are joined by, for example, welding or bonding.

As described above, the wire harness 1 of the present embodiment has the flexible printed circuit board 3, the chip fuse 6, the plate member 4, and the potting agent 5. The chip fuse 6 is mounted on the flexible printed circuit board 3. The plate member 4 has a flat plate-shaped plate body 40 having a frame shape and a cylindrical peripheral wall 41. The peripheral wall 41 protrudes from the plate body 40 in the thickness direction T of the plate body 40.

The plate body 40 is fixed to the flexible printed circuit board 3 so as to surround the chip fuse 6 by the peripheral wall 41. The potting agent 5 is charged in the space portion 4s surrounded by the peripheral wall 41 and covers the chip fuse 6. In the wire harness 1 of the present embodiment, it is possible to reduce the weight of the plate member 4 by reducing the thickness of the plate body 40.

The plate member 4 of the present embodiment is formed of a metal plate. The peripheral wall 41 is formed by the burring process to a metal plate. Such a structure allows to reduce the wall thickness of the entire plate member 4.

The flexible printed circuit board 3 of the present embodiment has the trunk line 30 and the branch portion 31. The branch portion 31 is branched from the trunk line 30 and is connected to the bus bar 10. The chip fuse 6 is mounted on the branch portion 31. The plate body 40 is fixed to the branch portion 31 so as to surround the chip fuse 6 by the peripheral wall 41. The weight reduction of the plate member 4 reduces the load on the branch portion 31.

The plate member 4 of the present embodiment is a member formed of a conductive metal, and electrically connects the chip fuse 6 and the bus bar 10. The number of components can be reduced by forming the space portion 4s for the potting agent 5 by terminal members.

Note that the position where the chip fuse 6 is mounted is not limited to the branch portion 31. The chip fuse 6 may be mounted on the trunk line 30. The number of the chip fuses 6 accommodated in the space portion 4s is not limited to one. The plate body 40 of the plate member 4 may be fixed to the flexible printed circuit board 3 so as to surround the plurality of chip fuses 6 by the peripheral wall 41. In this case, the potting agent 5 can be charged in the space portion 4s surrounded by the peripheral wall 41 and cover the plurality of chip fuses 6.

The contents disclosed in the above embodiments can be performed in combination as appropriate.

In a wire harness according to the present embodiment, a plate member has a flat plate-shaped plate body having a frame shape, and a cylindrical peripheral wall protruding from the plate body in a thickness direction of the plate body. The plate body is fixed to a flexible printed circuit board so as to surround a chip fuse by the peripheral wall. A potting agent is charged in a space portion surrounded by the peripheral wall and covers the chip fuse. The wire harness according to the present embodiment has an effect that the weight of the plate member can be reduced while realizing the required depth of the potting layer.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wire harness comprising:
a flexible printed circuit board;
a chip fuse mounted on the flexible printed circuit board;
a plate member having a flat plate-shaped plate body having a frame shape, and a cylindrical peripheral wall protruding from the plate body in a thickness direction of the plate body; and
a potting agent, wherein
the plate body is fixed to the flexible printed circuit board so as to surround the chip fuse by the peripheral wall, and
the potting agent is charged in a space portion surrounded by the peripheral wall and covers the chip fuse.

2. The wire harness according to claim 1, wherein
the plate member is formed of a metal plate, and
the peripheral wall is formed by a burring process to the metal plate.

3. The wire harness according to claim 1, wherein
the flexible printed circuit board has a trunk line and a branch portion that is branched from the trunk line and is connected to a bus bar,
the chip fuse is mounted on the branch portion, and
the plate body is fixed to the branch portion so as to surround the chip fuse by the peripheral wall.

4. The wire harness according to claim 1, wherein
the plate member is a member formed of a conductive metal and electrically connects the chip fuse and the bus bar.
